(19) United States
(12) Patent Application Publication
(10) Pub. No.: US 2026/0006753 A1
(43) Pub. Date: Jan. 1, 2026

(54) ELECTRONIC DEVICE ANTENNA USING HEAT SINK COMPONENTS

(71) Applicant: Microsoft Technology Licensing, LLC, Redmond, WA (US)

(72) Inventors: Sneha Rajeev SONDUR, Seattle, WA (US); Marc HARPER, Snohomish, WA (US); Chulmin HAN, Redmond, WA (US)

(73) Assignee: Microsoft Technology Licensing, LLC, Redmond, WA (US)

(21) Appl. No.: 18/756,893

(22) Filed: Jun. 27, 2024

(51) Int. Cl. H05K 7/20; G06F 1/16; G06F 1/20; H01Q 1/22; H01Q 13/10

(52) U.S. Cl. CPC H05K 7/2039; G06F 1/1698; G06F 1/203; H01Q 1/2266; H01Q 13/10; H05K 7/20336

(57) ABSTRACT

An electronic device includes one or more processing components that generate heat during operation. A heat sink is thermally coupled with the one or more processing components, such that the heat sink assembly dissipates at least a portion of the heat generated by the one or more processing components, wherein one or more components of the heat sink assembly are spaced away from a conductive chassis wall of the electronic device to form a cavity. An antenna feed line is disposed within the cavity, such that the antenna feed line and the cavity collectively form a cavity-backed slot-type antenna usable to transmit radio frequency (RF) signals.

### BACKGROUND

Wireless communication devices sometimes include integrated antennas to enable data communication. For instance, such antennas can enable wireless communication with other electronic devices—e.g., through transmission and reception of radio frequency (RF) signals.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

An electronic device includes one or more processing components that generate heat during operation. A heat sink is thermally coupled with the one or more processing components, such that the heat sink assembly dissipates at least a portion of the heat generated by the one or more processing components, wherein one or more components of the heat sink assembly are spaced away from a conductive chassis wall of the electronic device to form a cavity. An antenna feed line is disposed within the cavity, such that the antenna feed line and the cavity collectively form a cavity-backed slot-type antenna usable to transmit radio frequency (RF) signals.

### BRIEF DESCRIPTION OF THE DRAWINGS

FIG. 1 schematically shows an example electronic device including a processing component that generates heat during operation.

FIG. 2 schematically shows aspects of an example heat sink assembly of an electronic device.

FIG. 3 schematically shows aspects of an example heat sink assembly of an electronic device, in which heat sink components are spaced away from a conductive chassis wall to form a cavity.

FIG. 4 schematically shows aspects of another example heat sink assembly of an electronic device, in which heat sink components are spaced away from a conductive chassis wall to form a cavity.

FIG. 5 schematically shows aspects of another example heat sink assembly of an electronic device, in which heat sink components are spaced away from a conductive chassis wall to form a cavity.

FIG. 6 schematically shows another example heat sink assembly in which components are usable as a slot-type antenna.

FIG. 7 schematically shows an example computing system.

### DETAILED DESCRIPTION

It can be challenging to integrate antennas for wireless communication into electronic devices. For instance, wireless communication devices increasingly require compact and efficient antenna designs that can be integrated into the device's structure without compromising performance and aesthetics. Particularly, integrating antennas into devices with metal enclosures poses significant challenges due to the shielding effect of the metal, which obstructs the transmission and reception of radio frequency (RF) signals. Existing solutions often necessitate complicated antenna designs, such as the use of plastic windows or intricate patterns etched into the device's structure, to circumvent the metal's interference. These complex designs can compromise the aesthetic appeal and structural integrity of the device, making them less desirable for sleek, fully metallic enclosures. In addition, slot type antennas etched/attached into the inlet or exhaust vents of an actively cooled electronic device can cause flow resistance, which in turn impacts the heat dissipation capability of the thermal solution.

Accordingly, the present disclosure describes example arrangements for electronic devices in which components of a heat sink assembly are used both to manage heat produced by processing components of the electronic device and also function as part of an antenna usable to transmit and receive RF signals. More particularly, the electronic device comprises one or more processing components that generate heat during operation. Thermally coupled to these processing components is a heat sink assembly. The heat sink assembly is designed to dissipate at least a portion of the heat generated by the processing components. The heat sink assembly may include components such as finned heat sinks, heat pipes, vapor chambers, and/or fans, as examples. In some examples, one or more components of the heat sink assembly are strategically spaced away from a conductive chassis wall of the electronic device, thereby forming a cavity. Within this cavity is an antenna feed line. The placement of the antenna feed line within the cavity is such that it, in combination with the cavity itself, forms a cavity-backed slot-type antenna. This antenna is usable to transmit radio frequency (RF) signals, providing the device with the capability to communicate wirelessly.

In this manner, the arrangements described herein beneficially leverage the existing thermal management infrastructure of the electronic device, thereby reducing the need for additional space or components. The integration of the antenna feed line into the cavity ensures that the antenna is both functional and unobtrusive to airflow through the vents, maintaining the sleek and compact design of the electronic device. This approach not only addresses the challenge of incorporating antennas into fully metallic enclosures but also enhances the overall performance of the device by providing efficient thermal management and reliable wireless communication. The combination of the heat sink assembly and the cavity-backed slot-type antenna can beneficially enable a reduction in physical size and/or a reduction in cost of the electronic device.

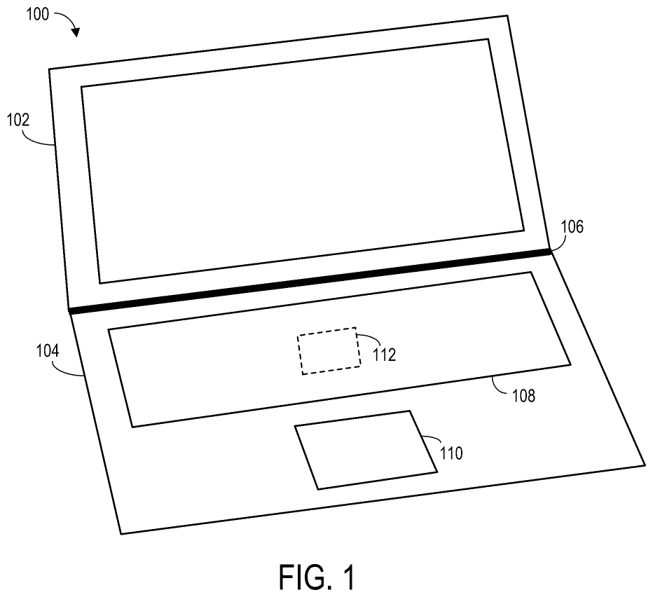

FIG. 1 schematically shows an example electronic device 100 in which the heat sink arrangements described herein may be implemented. In this example, the electronic device takes the form of a foldable computing device (e.g., a laptop computer) including a first portion 102 and a second portion 104 rotatably coupled with the first portion via a hinge 106. In this example, the first portion includes a computer display, while the second portion includes input devices usable by a human user to provide input to the electronic device—e.g., a keyboard 108 and a touchpad 110.

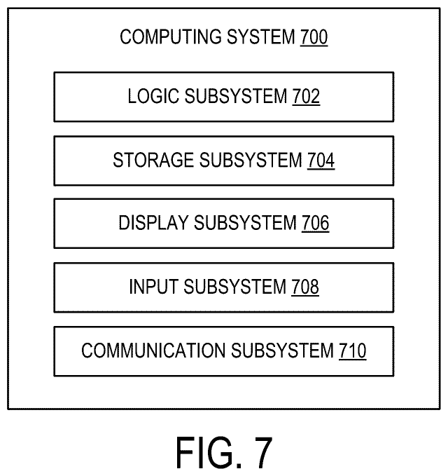

It will be understood, however, that electronic device 100 is a non-limiting example. In general, the arrangements described herein may be implemented in any suitable electronic devices including one or more processing components that generate heat, to beneficially enable wireless RF communication for such devices. An electronic device implementing the heat sink arrangements described herein may have any suitable capabilities, form factor, and hardware configuration. As one non-limiting example, the arrangements described herein may be implemented with computing system 700 described below with respect to FIG. 7.

In the example of FIG. 1, the electronic device 100 includes a processing component 112, shown in dashed lines to indicate that it is disposed within the second portion 104 of the electronic device. In general, an electronic device as described herein may include one or more processing components that generate heat during operation. These processing components may include, but are not limited to, central processing units (CPUs), graphics processing units (GPUs), and/or other integrated circuits. As one example, a processing component may take the form of logic subsystem 702 described below with respect to FIG. 7.

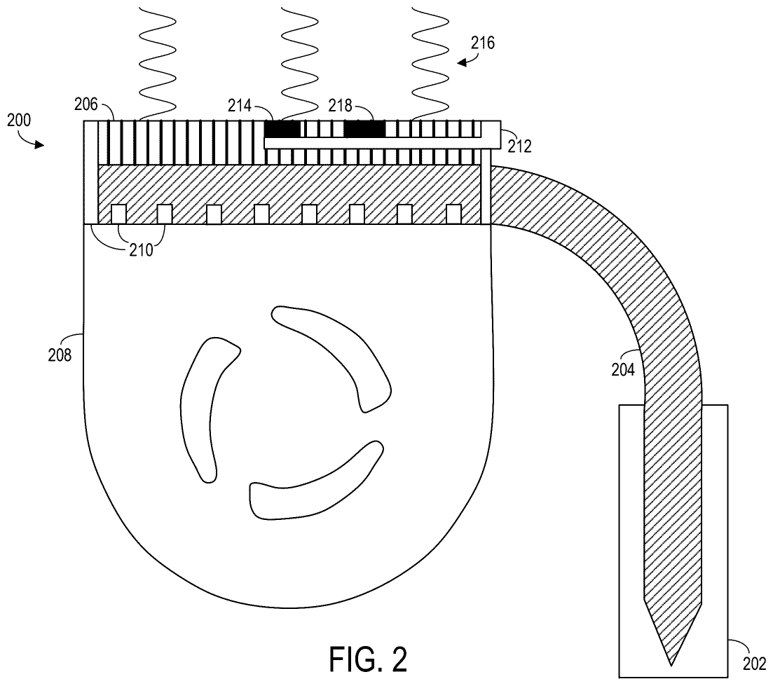

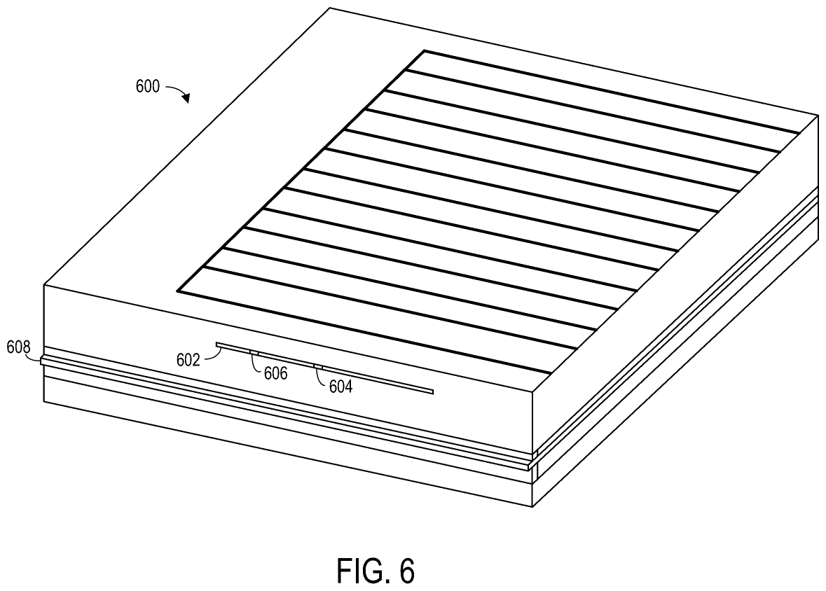

In order to manage heat produced by processing components during operation, the electronic device includes a heat sink assembly. FIG. 2 schematically shows aspects of an example heat sink assembly 200. It will be understood that the specific appearance and configuration of heat sink assembly 200 is highly simplified and presented only as a non-limiting example for the sake of illustration. In other examples, the specific components included in a heat sink assembly may take other suitable forms, have other appearances, and/or have other positions with respect to one another and with respect to other components of an electronic device. For instance, an example of another suitable heat sink assembly will be described below with respect to FIG. 6.

In FIG. 2, heat sink assembly 200 is thermally coupled with a processing component 202 and is used to dissipate at least a portion of the heat generated by the processing component during operation. To this end, the heat sink assembly includes various components used to transmit and dissipate heat. In this non-limiting example, the one or more components of the heat sink assembly 200 include a heat pipe 204, which contacts the processing component and transmits heat away from the processing component. In some examples, the heat pipe 204 may alternatively take the form of a vapor chamber, and/or may include a heat pipe and vapor chamber integrated into the same structure. Additionally, in this non-limiting example, the one or more components of the heat sink assembly 200 include a finned heat sink 206, which is heated by the heat pipe, and dissipates the heat into a surrounding atmosphere through a plurality of heat sink fins. The heat sink assembly 200 additionally includes a fan 208, which pushes air through the finned heat sink and promotes cooling of the components of the heat sink assembly. In some examples, the heat sink assembly may additionally or alternatively include a vapor chamber.

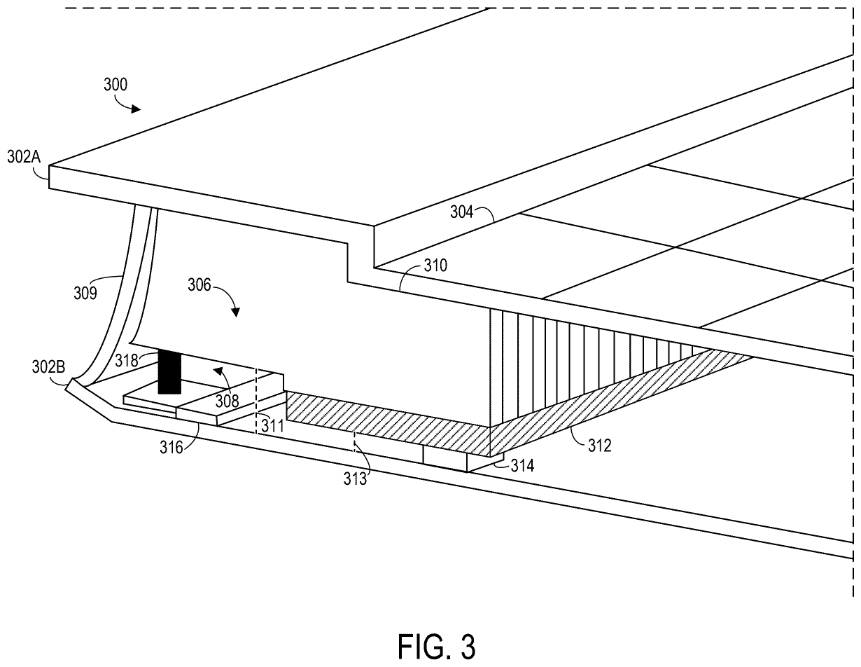

As will be described in more detail below, according to the arrangements described herein, aspects of the heat sink assembly may also be used to provide a cavity-backed slot-type antenna. To this end, in FIG. 2, the heat sink assembly 200 includes electronic grounding foam 210, which may serve as a border for the cavity of the antenna. The electronic grounding foam may be constructed from any suitable material—e.g., a suitable polymer substance to which a conductive coating has been applied. As will be illustrated with respect to FIGS. 3-5, the grounding foam may be disposed between the heat pipe and a conductive chassis wall of the electronic device. The grounding foam may beneficially provide electromagnetic and radio frequency (RF) grounding within the antenna system. This may reduce electromagnetic interference and enhance the overall performance of the antenna. By creating a stable RF grounding environment, the grounding foam may help to improve signal integrity, reduce noise, and ensure efficient transmission and reception of RF signals within the device.

Additionally, in this example, the electronic grounding foam 210 is castellated—e.g., separated into several individual pieces of foam, rather than one larger continuous piece. This may beneficially permit airflow from fan 208 to pass between individual pieces of the castellated grounding foam, improving the thermal performance of the electronic device, and preventing thermal hotspots from developing directly under the foam area on the conductive chassis. Additionally, or alternatively, castellation may be used to enhance electrical connections and improve grounding. For instance, the notches in the castellation may provide multiple points of contact, which can help to stabilize and distribute electrical currents more effectively, reduce impedance, and improve the overall performance and reliability of the device's grounding and RF systems.

FIG. 2 additionally shows a printed circuit board (PCB) 212, which is communicatively coupled with an antenna feed line 214. The PCB may couple the antenna feed line with other components of the electronic device, such as one or more processing components, and/or an antenna transceiver. In general, the antenna feed line, in combination with a cavity formed by components of the heat sink assembly, forms a cavity-backed slot-type antenna usable to transmit and/or receive RF signals. In the example of FIG. 2, the heat sink assembly 200 is used to transmit RF signals 216, represented as curved lines extending away from the finned heat sink 206. As non-limiting examples, the RF signals may include one or more of a 2.4 GHz frequency band and a 5-7 GHz frequency band. For instance, the antenna may be used to send and/or receive Wi-Fi signals.

Additionally, in this example, FIG. 2 depicts an RF tuning component 218 configured to perform one or more of impedance matching, signal tuning, or signal filtering, for RF signals sent and/or received by the antenna. The RF tuning component may be constructed from any suitable combination of capacitors, inductors, resistors, tunable filters, phase shifters, and/or other suitable hardware components, which may be integrated together—e.g., as a lumped component. This may beneficially improve the performance of the antenna system. For instance, the RF tuning component may beneficially serve to reduce signal loss and improve signal integrity, which may improve the efficiency, bandwidth, and reliability of the antenna system within the electronic device.

It will be understood that the “antenna feed line” and “RF tuning component” are simplified representations of components that may be used to enable transmission and reception of RF signals. In one example, RF signals may be generated by a transceiver in the electronic device, and carried by a transmission line to signal matching networks (e.g., disposed on PCB 212). RF signals from the matching networks may be carried to a conductive chassis wall of the device via a spring clip—e.g., contacting the chassis wall and a pad on the PCB. In the example of FIG. 2, each of these components are generically represented by the PCB 214 and antenna feed line 218.

FIG. 3 schematically shows aspects of an example heat sink assembly integrated into an electronic device 300. Specifically, in this example, FIG. 3 depicts the base portion of a computing device (e.g., a laptop computer), with a portion of the chassis cut away to reveal internal components. For instance, the components depicted in FIG. 3 may be integrated into the second portion 104 of electronic device 100 depicted in FIG. 1. However, as discussed above, it will be understood that the arrangements of components discussed herein and as depicted in FIGS. 3, 4, 5, and 6 may be integrated into any suitable electronic device, having any suitable capabilities, hardware configuration, and form factor. Furthermore, it will be understood that the specific configurations depicted in FIGS. 3, 4, 5, and 6 are simplified and non-limiting.

As shown, the electronic device 300 includes a first chassis wall 302A and a second chassis wall 302B. The chassis walls may be constructed from any suitable conductive materials to implement a slot-type antenna as discussed herein. As non-limiting examples, the conductive chassis walls may be constructed from suitable metals, such as aluminum or stainless steel. In this example, an input device 304 is integrated into the first conductive chassis wall 304. The input device may, for instance, take the form of a keyboard, such as keyboard 108 of electronic device 100. This enables the conductive chassis wall of the device to serve as a component of the slot-type antenna. As will be described in more detail below, either conductive wall may be used—e.g., either the wall on the same side as the input device, or the wall on the opposite side, which promotes flexibility in the electronic device's design.

Additionally, in FIG. 3, the electronic device 300 includes a heat sink assembly 306, which includes various components used to dissipate at least a portion of the heat generated by one or more processing components of the electronic device. As shown, components of the heat sink assembly 306 are spaced away from the conductive chassis wall of the electronic device to form a cavity 308. In this manner, the heat sink assembly and the conductive chassis wall form a cavity of a cavity-backed slot-type antenna, which is usable to send and/or receive RF signals. For instance, RF signals may be transmitted and received through a vent cover 309 of the electronic device, which may be constructed from a suitable non-conductive material, such as plastic. A cavity-backed slot-type antenna operates by combining a slot in a conductive surface with a resonant cavity to enhance the antenna's performance. For instance, in this example, the slot may be defined at the edge of the electronic device by the gap between the conductive chassis wall and conductive components of the heat sink assembly.

More particularly, in this example, the heat sink assembly 306 includes a finned heat sink 310 and a heat pipe 312, each of which serve to dissipate heat generated by processing components as discussed above. In other words, these components serve two different purposes-managing thermal energy produced by the device during operation, as well as serving as components of a slot-type antenna, which enables a reduction in the number of components included in the electronic device. Additionally, in this example, each of the finned heat sink and heat pipe are spaced away from the conductive chassis wall to form cavity 308. Castellated electronic grounding foam 314 is disposed between the heat pipe and the conductive chassis wall, serving as an electronically-grounding border for the cavity.

The properties of the cavity-backed slot-type antenna depend at least in part on the dimensions of the cavity. Thus, the distance between the heat sink and the conductive chassis wall may have any suitable value, depending on the desired thermal and RF characteristics of the electronic device. As one non-limiting example, a length 311 of the cavity between the finned heat sink and the conductive chassis wall may be between 1.5 mm and 5 mm. Similarly, the distance between the heat pipe and the conductive chassis wall may have any suitable value. As one non-limiting example, a length 313 of the cavity between the heat pipe and the conductive chassis wall may be between 1 mm and 3 mm. These values can balance thermal dissipation (e.g., enabling suitable airflow through the heat sink assembly) against RF reception and transmission (e.g., enabling generation and detection of RF signals in a desired frequency spectrum, such as for Wi-Fi communication).

Additionally, in this example, the electronic device includes a PCB 316 communicatively coupled with an antenna feed line 318. As discussed above, the antenna feed line together with the cavity forms a cavity-backed slot-type antenna. For instance, when the antenna feed line is excited with RF signals (e.g., from an antenna transceiver also connected to PCB 316), the RF signals resonate within the cavity formed by the heat sink assembly and conductive chassis wall. RF signals may then radiate away from a slot, defined by the gap between the conductive chassis wall and the finned heat sink. The cavity helps to direct and shape the RF waves, resulting in a more focused and efficient radiation pattern. Similarly, incoming RF signals may be captured by the slot and cavity and channeled through the feed line for decoding.

As discussed above, the heat sink assembly 306 is positioned between the first conductive chassis wall 302A and the second conductive chassis wall 302B. An input device 304 is integrated into the first conductive chassis wall. In the example of FIG. 3, the cavity is bordered by the second conductive chassis wall—e.g., in other words, the cavity is formed on the side of the electronic device that is opposite from the input device. However, it will be understood that this need not always be the case. Rather, in some examples, the cavity may be bordered by the first conductive chassis wall, on the same side as the input device. This enables flexibility in the design of the electronic device, while still providing the thermal management and slot-type antenna functionality described herein.

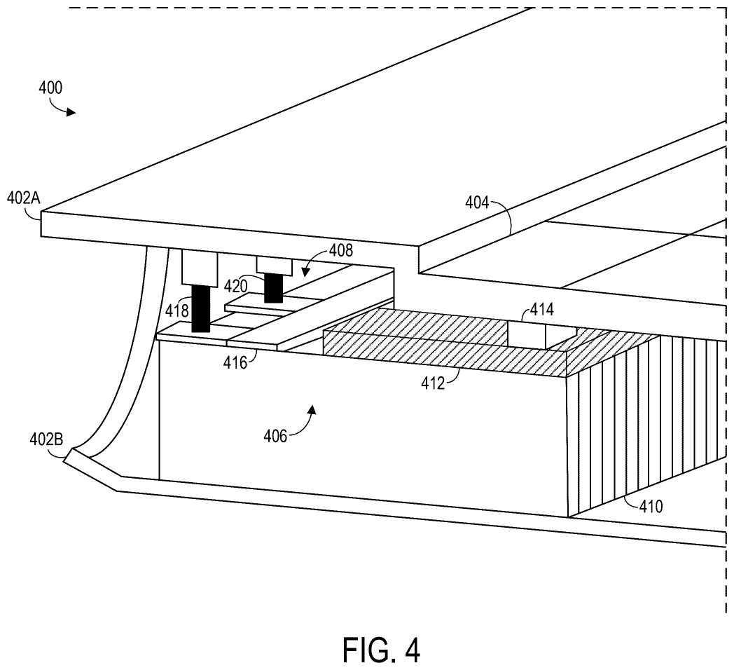

This scenario is schematically illustrated with respect to FIG. 4, showing another example electronic device 400. In this example, FIG. 4 depicts the base portion of a computing device with a portion of the chassis cut away to reveal internal components. Electronic device 400 includes a first conductive chassis wall 402A and a second conductive chassis wall 402B. An input device 404 is integrated into the first conductive chassis wall, and a heat sink assembly 406 is disposed between the first conductive chassis wall and the second conductive chassis wall. Components of the heat sink assembly are spaced away from conductive chassis wall 402B to form a cavity 408, which serves as the cavity of a cavity-backed slot-type antenna. In other words, in this example, the cavity is bordered by the first conductive chassis wall, rather than the second conductive chassis wall, and thus is on the same side of the electronic device as the input device.

Additionally, electronic device 400 includes a finned heat sink 410 and a heat pipe 412. Castellated electronic grounding foam 414 is positioned between the heat pipe and the second conductive chassis wall. Within cavity 408, a PCB 416 is communicatively coupled with an antenna feed line 418, and an RF tuning component 420. As discussed above, the antenna feed line may be excited with RF signals that then resonate within the cavity, such that the antenna feed line and cavity together constitute a cavity-backed slot type antenna. Furthermore, as discussed above, the antenna feed line and RF tuning component together generically represent any suitable collection of components usable for generating and receiving RF signals within the slot-type antenna. For instance, the RF tuning component may be grounded to the PCB via a PCB pad, and conductively coupled with the conductive chassis wall via a spring clip.

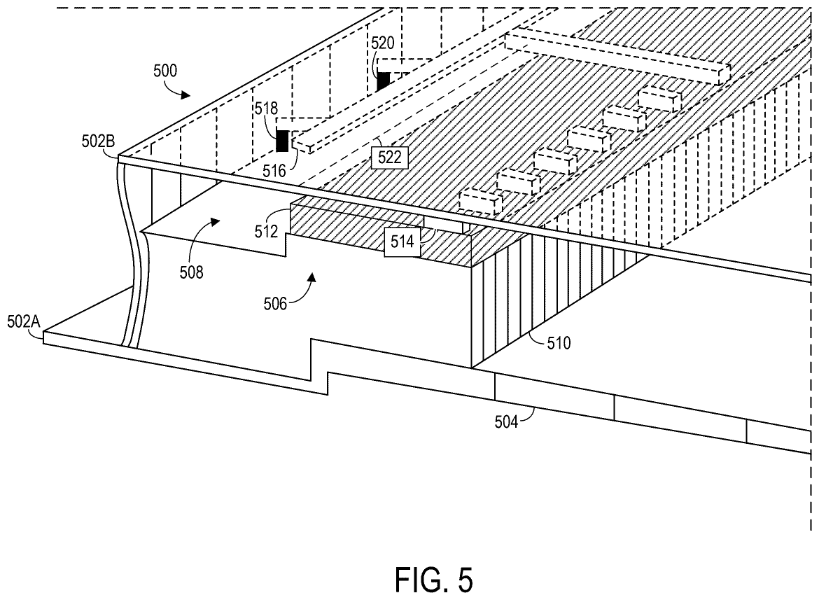

FIG. 5 schematically shows another example electronic device 500, including a first conductive chassis wall 502A and a second conductive chassis wall 502B. Similar to the example electronic devices 300 and 400, an input device 504 is integrated into the first conductive chassis wall, and a heat sink assembly 506 is disposed between the first and second conductive chassis walls. Components of the heat sink assembly are spaced away from the second conductive chassis wall to form a cavity 508.

In the example electronic device 500 illustrated in FIG. 5, the second conductive chassis wall is depicted as being transparent to reveal more of the components of the heat sink assembly within the electronic device. As shown, the heat sink assembly includes a finned heat sink 510, a heat pipe 512, and electronic grounding foam 514 disposed between the heat pipe and conductive chassis wall. As discussed above, the electronic grounding foam is castellated in this example implementation, and thus is divided into separate pieces rather than a single continuous piece. The electronic device additionally includes a PCB 516, which is communicatively coupled with an antenna feed line 518 and RF tuning component 520.

As discussed above, the dimensions of the cavity influence the RF properties of the cavity-backed slot-type antenna. The length of the cavity in a cavity-backed slot-type antenna is closely related to the wavelength of the RF signals it is designed to transmit and receive. Thus, depending on the implementation, the length 522 of the cavity may vary. As one non-limiting example, the length of the cavity may be equal to or greater than 62 mm, which may support transmission and/or reception of RF signals suitable for Wi-Fi data communication.

FIG. 6 schematically depicts another example implementation in which aspects of a heat sink assembly may be dual-purposed as a slot-type antenna for RF signal transmission. Specifically, FIG. 6 schematically shows an example finned heat sink 600. As with the other heat sink assemblies discussed above, heat sink 600 may be integrated into any suitable electronic device, having any suitable capabilities, hardware configuration, and form factor. As one non-limiting example, heat sink 600 may be integrated into a cloud computing device, such as a server computer. The heat sink is thermally coupled with one or more processing devices of the computing device, such that at least a portion of the heat generated by the processing devices during operation is dissipated by the heat sink. In some examples, heat sink 600 may be integrated into computing system 700 described below with respect to FIG. 7.

In FIG. 6, a slot 602 is formed in heat sink 600. Due to the presence of slot 602, the heat sink may be usable as a slot-type antenna to send and/or receive RF signals. To this end, in FIG. 6, the heat sink includes an antenna feed line 604 disposed within slot 602. Similarly, heat sink 600 includes an RF tuning component 606 disposed within slot 602. As discussed above, excitation of the antenna feed line may cause RF signals to radiate outwards from the slot, enabling wireless transmission of data to other electronic devices. Similarly, RF signals emitted by other electronic devices may be captured by slot 602 and cause excitation of the antenna feed line, enabling such RF signals to be decoded as data. The RF tuning component may take the form of any suitable combination of hardware components for impedance matching, signal tuning, and/or signal filtering, such as capacitors, inductors, resistors, phase shifters, etc. Such components may in some cases be integrated together as a single structure—e.g., as a lumped component.

Additionally, heat sink 600 includes an RF grounding fence 608, which may be used to provide electromagnetic shielding and grounding around the antenna's radiating elements. This may beneficially help to block external RF signals that could interfere with the antenna's operation, thereby enhancing the signal-to-noise ratio.

FIG. 7 schematically shows a simplified representation of a computing system 700 that integrates one or more of the components described herein and/or is configured to provide any to all of the functionality described herein. Computing system 700 may take the form of one or more personal computers, network-accessible server computers, tablet computers, home-entertainment computers, gaming devices, mobile computing devices, mobile communication devices (e.g., smart phone), virtual/augmented/mixed reality computing devices, embedded computing devices, and/or other computing devices.

Computing system 700 includes a logic subsystem 702 and a storage subsystem 704. Computing system 700 may optionally include a display subsystem 706, input subsystem 708, communication subsystem 710, and/or other subsystems not shown in FIG. 7.

Logic subsystem 702 includes one or more physical devices configured to execute instructions. For example, the logic subsystem may be configured to execute instructions that are part of one or more applications, services, or other logical constructs. The logic subsystem may include one or more hardware processors configured to execute software instructions. Additionally, or alternatively, the logic subsystem may include one or more hardware or firmware devices configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely-accessible, networked computing devices configured in a cloud-computing configuration.

Storage subsystem 704 includes one or more physical devices configured to temporarily and/or permanently hold computer information such as data and instructions executable by the logic subsystem. When the storage subsystem includes two or more devices, the devices may be collocated and/or remotely located. Storage subsystem 704 may include volatile, nonvolatile, dynamic, static, read/write, read-only, random-access, sequential-access, location-addressable, file-addressable, and/or content-addressable devices. Storage subsystem 704 may include removable and/or built-in devices. When the logic subsystem executes instructions, the state of storage subsystem 704 may be transformed—e.g., to hold different data.

Aspects of logic subsystem 702 and storage subsystem 704 may be integrated together into one or more hardware-logic components. Such hardware-logic components may include program- and application-specific integrated circuits (PASIC/ASICs), program- and application-specific standard products (PSSP/ASSPs), system-on-a-chip (SOC), and complex programmable logic devices (CPLDs), for example.

The logic subsystem and the storage subsystem may cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine may be instantiated by a single computing device, or a machine may include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality may optionally be saved as one or more unexecuted modules on one or more suitable storage devices.

When included, display subsystem 706 may be used to present a visual representation of data held by storage subsystem 704. This visual representation may take the form of a graphical user interface (GUI). Display subsystem 706 may include one or more display devices utilizing virtually any type of technology. In some implementations, display subsystem may include one or more virtual-, augmented-, or mixed reality displays.

When included, input subsystem 708 may comprise or interface with one or more input devices. An input device may include a sensor device or a user input device. Examples of user input devices include a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition.

When included, communication subsystem 710 may be configured to communicatively couple computing system 700 with one or more other computing devices. Communication subsystem 710 may include wired and/or wireless communication devices compatible with one or more different communication protocols. The communication subsystem may be configured for communication via personal-, local- and/or wide-area networks.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

In an example, an electronic device comprises: one or more processing components that generate heat during operation; a heat sink assembly thermally coupled with the one or more processing components, such that the heat sink assembly dissipates at least a portion of the heat generated by the one or more processing components, wherein one or more components of the heat sink assembly are spaced away from a conductive chassis wall of the electronic device to form a cavity; and an antenna feed line disposed within the cavity, wherein the antenna feed line and the cavity collectively form a cavity-backed slot-type antenna usable to transmit radio frequency (RF) signals. In this example or any other example, the one or more components of the heat sink assembly include a finned heat sink. In this example or any other example, a length of the cavity between the finned heat sink and the conductive chassis wall is between 1.5 mm and 5 mm. In this example or any other example, the one or more components of the heat sink assembly include a heat pipe. In this example or any other example, a length of the cavity between the heat pipe and the conductive chassis wall is between 1 mm and 3 mm. In this example or any other example, the electronic device further comprises electronic grounding foam disposed between the heat pipe and the conductive chassis wall. In this example or any other example, the one or more components of the heat sink assembly include a vapor chamber. In this example or any other example, the conductive chassis wall is a first conductive chassis wall of the electronic device, wherein the heat sink assembly is disposed between the first conductive chassis wall and a second conductive chassis wall, such that the cavity is bordered by the first conductive chassis wall, and wherein an input device is integrated into the first conductive chassis wall. In this example or any other example, the conductive chassis wall is a second conductive chassis wall of the electronic device, wherein the heat sink assembly is disposed between the second conductive chassis wall and a first conductive chassis wall, such that the cavity is bordered by the second conductive chassis wall, and wherein an input device is integrated into the first conductive chassis wall. In this example or any other example, the electronic device further comprises an RF tuning component disposed within the cavity configured to perform one or more of impedance matching, signal tuning, or signal filtering.

In an example, a foldable computing device comprises: a first portion; and a second portion rotatably coupled with the first portion via a hinge, the second portion comprising: one or more processing components that generate heat during operation; a heat sink assembly thermally coupled with the one or more processing components, such that the heat sink assembly dissipates at least a portion of the heat generated by the one or more processing components, wherein one or more components of the heat sink assembly are spaced away from a conductive chassis wall of the foldable computing device to form a cavity; and an antenna feed line disposed within the cavity, wherein the antenna feed line and the cavity collectively form a cavity-backed slot-type antenna usable to transmit radio frequency (RF) signals. In this example or any other example, the one or more components of the heat sink assembly include a finned heat sink. In this example or any other example, the one or more components of the heat sink assembly include a heat pipe. In this example or any other example, the foldable computing device further comprises electronic grounding foam disposed between the heat pipe and the conductive chassis wall. In this example or any other example, the electronic grounding foam is castellated. In this example or any other example, the conductive chassis wall is a first conductive chassis wall of the foldable electronic device, wherein the heat sink assembly is disposed between the first conductive chassis wall and a second conductive chassis wall, such that the cavity is bordered by the first conductive chassis wall, and wherein an input device is integrated into the first conductive chassis wall. In this example or any other example, the conductive chassis wall is a second conductive chassis wall of the foldable computing device, wherein the heat sink assembly is disposed between the second conductive chassis wall and a first conductive chassis wall, such that the cavity is bordered by the second conductive chassis wall, and wherein an input device is integrated into the first conductive chassis wall.

In an example, a computing device comprises: one or more processing components that generate heat during operation; a heat sink assembly thermally coupled with the one or more processing components, such that the heat sink assembly dissipates at least a portion of the heat generated by the one or more processing components, wherein a slot is formed in a finned heat sink of the heat sink assembly; and an antenna feed line disposed within the slot formed in the finned heat sink, such that the antenna feed line and the slot collectively form a slot-type antenna usable to transmit radio frequency (RF) signals. In this example or any other example, the heat sink assembly includes an RF grounding fence configured to provide electromagnetic shielding and grounding. In this example or any other example, the heat sink assembly includes an RF tuning component disposed within the slot configured to perform one or more of impedance matching, signal tuning, or signal filtering.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. An electronic device, comprising:
one or more processing components that generate heat during operation;
a heat sink assembly thermally coupled with the one or more processing components, such that the heat sink assembly dissipates at least a portion of the heat generated by the one or more processing components, wherein one or more components of the heat sink assembly are spaced away from a conductive chassis wall of the electronic device to form a cavity; and
an antenna feed line disposed within the cavity, wherein the antenna feed line and the cavity collectively form a cavity-backed slot-type antenna usable to transmit radio frequency (RF) signals.

2. The electronic device of claim 1, wherein the one or more components of the heat sink assembly include a finned heat sink.

3. The electronic device of claim 2, wherein a length of the cavity between the finned heat sink and the conductive chassis wall is between 1.5 mm and 5 mm.

4. The electronic device of claim 1, wherein the one or more components of the heat sink assembly include a heat pipe.

5. The electronic device of claim 4, wherein a length of the cavity between the heat pipe and the conductive chassis wall is between 1 mm and 3 mm.

6. The electronic device of claim 4, further comprising electronic grounding foam disposed between the heat pipe and the conductive chassis wall.

7. The electronic device of claim 1, wherein the one or more components of the heat sink assembly include a vapor chamber.

8. The electronic device of claim 1, wherein the conductive chassis wall is a first conductive chassis wall of the electronic device, wherein the heat sink assembly is disposed between the first conductive chassis wall and a second conductive chassis wall, such that the cavity is bordered by the first conductive chassis wall, and wherein an input device is integrated into the first conductive chassis wall.

9. The electronic device of claim 1, wherein the conductive chassis wall is a second conductive chassis wall of the electronic device, wherein the heat sink assembly is disposed between the second conductive chassis wall and a first conductive chassis wall, such that the cavity is bordered by the second conductive chassis wall, and wherein an input device is integrated into the first conductive chassis wall.

10. The electronic device of claim 1, further comprising an RF tuning component disposed within the cavity configured to perform one or more of impedance matching, signal tuning, or signal filtering.

11. A foldable computing device, comprising:
a first portion; and
a second portion rotatably coupled with the first portion via a hinge, the second portion comprising:
one or more processing components that generate heat during operation;
a heat sink assembly thermally coupled with the one or more processing components, such that the heat sink assembly dissipates at least a portion of the heat generated by the one or more processing components, wherein one or more components of the heat sink assembly are spaced away from a conductive chassis wall of the foldable computing device to form a cavity; and
an antenna feed line disposed within the cavity, wherein the antenna feed line and the cavity collectively form a cavity-backed slot-type antenna usable to transmit radio frequency (RF) signals.

12. The foldable computing device of claim 11, wherein the one or more components of the heat sink assembly include a finned heat sink.

13. The foldable computing device of claim 11, wherein the one or more components of the heat sink assembly include a heat pipe.

14. The foldable computing device of claim 13, further comprising electronic grounding foam disposed between the heat pipe and the conductive chassis wall.

15. The foldable computing device of claim 14, wherein the electronic grounding foam is castellated.

16. The foldable computing device of claim 11, wherein the conductive chassis wall is a first conductive chassis wall of the foldable electronic device, wherein the heat sink assembly is disposed between the first conductive chassis wall and a second conductive chassis wall, such that the cavity is bordered by the first conductive chassis wall, and wherein an input device is integrated into the first conductive chassis wall.

17. The foldable computing device of claim 11, wherein the conductive chassis wall is a second conductive chassis wall of the foldable computing device, wherein the heat sink assembly is disposed between the second conductive chassis wall and a first conductive chassis wall, such that the cavity is bordered by the second conductive chassis wall, and wherein an input device is integrated into the first conductive chassis wall.

18. A computing device comprising:
one or more processing components that generate heat during operation;
a heat sink assembly thermally coupled with the one or more processing components, such that the heat sink assembly dissipates at least a portion of the heat generated by the one or more processing components, wherein a slot is formed in a finned heat sink of the heat sink assembly; and
an antenna feed line disposed within the slot formed in the finned heat sink, such that the antenna feed line and the slot collectively form a slot-type antenna usable to transmit radio frequency (RF) signals.

19. The computing device of claim 18, wherein the heat sink assembly includes an RF grounding fence configured to provide electromagnetic shielding and grounding.

20. The computing device of claim 18, wherein the heat sink assembly includes an RF tuning component disposed within the slot configured to perform one or more of impedance matching, signal tuning, or signal filtering.
